(19) United States
(12) Patent Application Publication
(10) Pub. No.: US 2026/0040862 A1
(43) Pub. Date: Feb. 5, 2026

(54) SUBSTRATE LOADING APPARATUS, SUBSTRATE PROCESSING SYSTEM INCLUDING THE SAME, AND SUBSTRATE PROCESSING METHOD USING THE SAME

(71) Applicant: Samsung Electronics Co., Ltd., Suwon-si (KR)

(72) Inventors: Chanwook PARK, Suwon-si (KR); JUSUK KANG, Suwon-si (KR); JONGHO PARK, Suwon-si (KR); Hyun YANG, Suwon-si (KR); JAEMOK JUNG, Suwon-si (KR); Tae Oh HA, Suwon-si (KR)

(21) Appl. No.: 19/199,475

(22) Filed: May 6, 2025

(30) Foreign Application Priority Data
Jul. 30, 2024 (KR) 10-2024-0100748

(51) Int. Cl. H01L 21/67; C23C 14/56; H01L 21/3065; H01L 21/677

(52) U.S. Cl. CPC H01L 21/67051; C23C 14/566; H01L 21/3065; H01L 21/67778

(57) ABSTRACT

A substrate loading apparatus includes a housing that provides a space where a substrate is configured to be disposed, a transfer track in the housing on an upper side of the housing, and a particle removal device connected to the transfer track. The particle removal device includes a nozzle configured to inject a gas and a module housing that has an intake hole. When viewed in plan, the intake hole surrounds the nozzle.

### CROSS-REFERENCE TO RELATED APPLICATION

This U.S. nonprovisional application claims priority under 35 U.S.C § 119 to Korean Patent Application No. 10-2024-0100748 filed on Jul. 30, 2024 in the Korean Intellectual Property Office, the disclosure of which is hereby incorporated by reference in its entirety.

### BACKGROUND

Aspects of the present inventive concepts relate to a substrate loading apparatus, a substrate processing system including the same, and a substrate processing method using the same, and more particularly, to a substrate loading apparatus the removes contaminant particles on a substrate surface, a substrate processing system including the same, and a substrate processing method using the same.

A semiconductor facility may include a loadlock chamber for transferring substrates between a front opening unified pod (FOUP) where the substrates are stored and a substrate processing apparatus for performing semiconductor processes. As semiconductor devices become reduced in size, contaminant particles present on a surface of the substrate have begun to significantly affect an operation of the semiconductor device. Therefore, it has become desirable to eliminate contaminant particles on the surface of the substrate.

### SUMMARY

Aspects of the present inventive concepts provide a substrate loading apparatus for removing contaminant particles on a substrate, a substrate processing system including the same, and a substrate processing method using the same.

Aspects of the present inventive concepts provide a substrate loading apparatus for preventing semiconductor devices from failure to increase productivity of semiconductor devices, a substrate processing system including the same, and a substrate processing method using the same.

The object of the present inventive concepts is not limited to the mentioned above, and other objects which have not been mentioned above will be clearly understood to those skilled in the art from the following description.

According to some embodiments of the present inventive concepts, a substrate loading apparatus may include: a housing that provides a space where a substrate is configured to be disposed; a transfer track in the housing on an upper side of the housing; and a particle removal device connected to the transfer track, wherein the particle removal device includes: a nozzle configured to inject a gas; and a module housing that has an intake hole, and wherein, when viewed in plan, the intake hole surrounds the nozzle.

According to some embodiments of the present inventive concepts, a substrate processing system may include: a substrate loading apparatus that includes a transfer track and a particle removal device that are connected to each other; and a substrate processing apparatus connected to the substrate loading apparatus, wherein the particle removal device includes a nozzle and an intake hole adjacent to the nozzle, and wherein the transfer track is configured to move the particle removal device.

According to some embodiments of the present inventive concepts, a substrate processing method may include: transferring a substrate to a substrate processing apparatus; and processing the substrate, wherein the transferring of the substrate includes: preparing the substrate in a substrate loading apparatus that includes a particle removal device; removing contaminant particles on the substrate using the particle removal device; and changing an internal pressure of the substrate loading apparatus, wherein the removing of the contaminant particles includes moving the particle removal device on the substrate.

### BRIEF DESCRIPTION OF DRAWINGS

FIG. 1 illustrates a plan view showing a substrate processing system according to some embodiments of the present inventive concepts.

FIG. 2 illustrates a perspective view showing a substrate loading apparatus according to some embodiments of the present inventive concepts.

FIG. 3 illustrates a cross-sectional view taken along line A-A′ of FIG. 2, showing a substrate loading apparatus according to some embodiments of the present inventive concepts.

FIG. 4 illustrates an enlarged view of section X depicted in FIG. 3, showing a particle removal device according to some embodiments of the present inventive concepts.

FIGS. 5 and 6 illustrate bottom views showing a particle removal device according to some embodiments of the present inventive concepts.

FIGS. 7 to 9 illustrate diagrams showing a substrate processing apparatus according to some embodiments of the present inventive concepts.

FIG. 10 illustrates a flow chart showing a substrate processing method according to some embodiments of the present inventive concepts.

FIG. 11 illustrates a diagram showing a method of removing contaminant particles according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

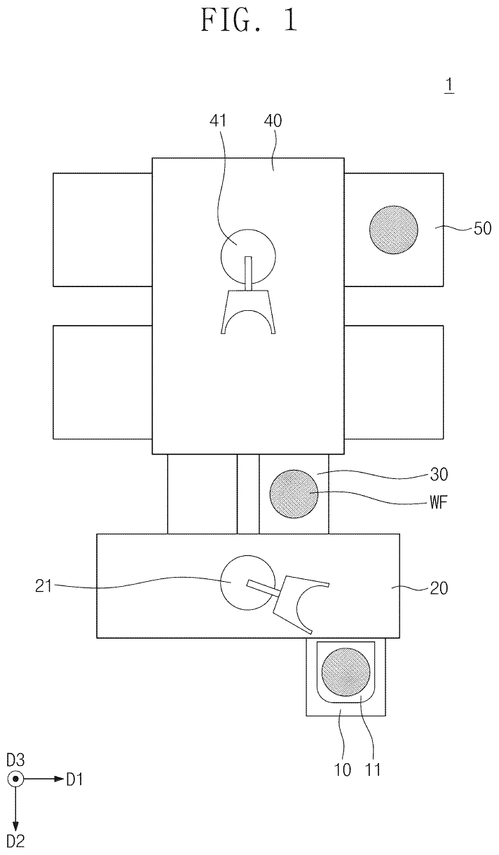

FIG. 1 illustrates a plan view showing a substrate processing system according to some embodiments of the present inventive concepts.

Referring to FIG. 1, a substrate processing system 1 may be provided. The substrate processing system 1 according to some embodiments of the present inventive concepts may be a single system consisting of a plurality of apparatuses capable of performing a semiconductor process on a surface of a substrate WF. In this description, the term “substrate WF” may include a semiconductor device integrated on a silicon (Si) wafer, but the present inventive concepts are not limited thereto. The substrate processing system 1 may include a load port 10, an interface module 20, a substrate loading apparatus 30, a substrate transfer apparatus 40, and a substrate processing apparatus 50.

A front opening unified pod (FOUP) 11 that stores the substrate WF may be positioned on the load port 10. When the FOUP 11 is positioned on the load port 10, the load port 10 may rigidly fix or hold the FOUP 11 in place. The load port 10 may be docked to allow the FOUP 11 and the interface module 20 to contact each other. The substrate WF in the FOUP 11 may enter or exit the substrate processing system 1 through the load port 10. For example, the number of load ports 10 present in the substrate processing system 1 may be one to five, but the present inventive concepts are not limited thereto.

The interface module 20 may be positioned between the load port 10 and the substrate loading apparatus 30. The interface module 20 may be connected to the load port 10 and the substrate loading apparatus 30. The load port 10 and the substrate loading apparatus 30 may be spaced apart from each other across the interface module 20. The interface module 20 may include a first robot arm 21 therein. The first robot arm 21 of the interface module 20 may transfer the substrate WF in the FOUP 11 to the substrate loading apparatus 30. In addition, the first robot arm 21 of the interface module 20 may transfer the substrate WF in the substrate loading apparatus 30 to the FOUP 11. For example, the interface module 20 may be an equipment front end module (EFEM).

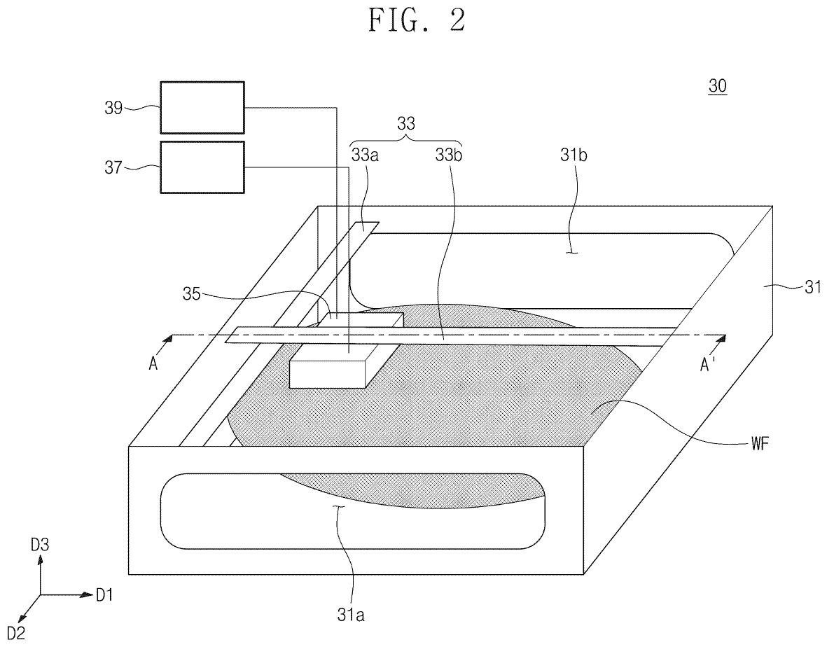

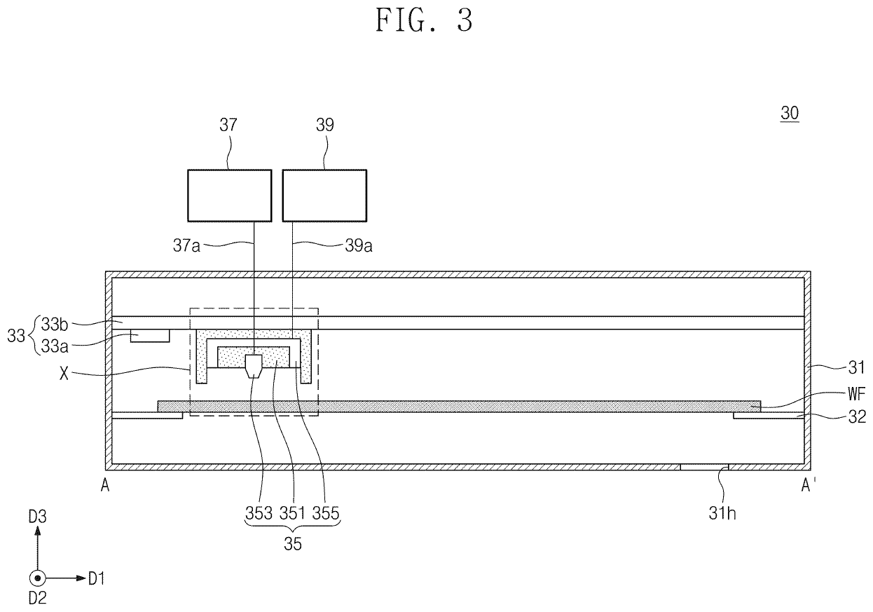

The substrate loading apparatus 30 may be positioned between the interface module 20 and the substrate transfer apparatus 40. The substrate loading apparatus 30 may be connected to the interface module 20 and the substrate transfer apparatus 40. The interface module 20 and the substrate transfer apparatus 40 may be spaced apart from each other across the substrate loading apparatus 30. The substrate WF in the interface module 20 may be transferred through the substrate loading apparatus 30 to the substrate transfer apparatus 40. Alternatively, the substrate WF in the substrate transfer apparatus 40 may be transferred through the substrate loading apparatus 30 to the interface module 20. For example, the substrate loading apparatus 30 may be a loadlock chamber. The substrate loading apparatus 30 may be provided in plural, but the present inventive concepts are not limited thereto. The substrate loading apparatus 30 will be further discussed in detail with reference to FIGS. 2 and 3.

The substrate transfer apparatus 40 may be positioned between the substrate processing apparatus 50 and the substrate loading apparatus 30. The substrate transfer apparatus 40 may be connected to the substrate processing apparatus 50 and the substrate loading apparatus 30. The substrate transfer apparatus 40 may include a second robot arm 41 therein. The second robot arm 41 of the substrate transfer apparatus 40 may transfer the substrate WF in the substrate loading apparatus 30 to the substrate processing apparatus 50. In addition, the second robot arm 41 of the substrate transfer apparatus 40 may transfer the substrate WF in the substrate processing apparatus 50 to the substrate loading apparatus 30. The substrate transfer apparatus 40 may be connected to a pump. An interior of the substrate transfer apparatus 40 may adopt a vacuum state by the pump. For example, the pressure in the interior of the substrate transfer apparatus 40 may be controlled using the pump. A single substrate transfer apparatus 40 may be connected to a plurality of substrate processing apparatuses 50, but the present inventive concepts are not limited thereto. For example, the substrate transfer apparatus 40 may be a transfer module chamber.

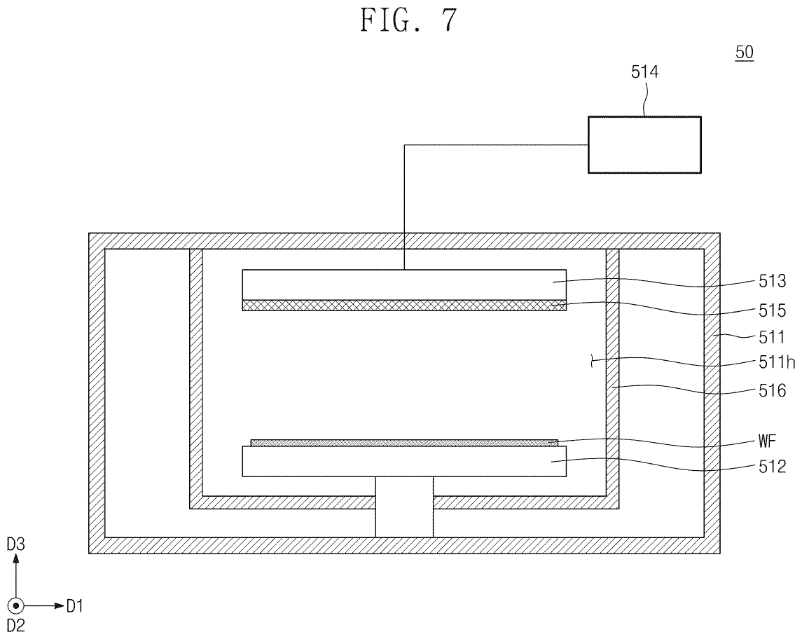

The substrate processing apparatus 50 may be positioned on one side of the substrate transfer apparatus 40. The substrate processing apparatus 50 may be connected to the substrate transfer apparatus 40. The substrate processing apparatus 50 may be a facility that performs a semiconductor process. For example, the semiconductor process may include an exposure process, an etching process, a deposition process, a cleaning process, and/or an ion implantation process. The substrate processing apparatus 50 may be provided in plural, but the present inventive concepts are not limited thereto. The substrate processing apparatus 50 will be further discussed in detail with reference to FIGS. 7 to 9.

FIG. 2 illustrates a perspective view showing a substrate loading apparatus 30 according to some embodiments of the present inventive concepts. FIG. 3 illustrates a cross-sectional view taken along line A-A′ of FIG. 2, showing a substrate loading apparatus according to some embodiments of the present inventive concepts.

Referring to FIGS. 2 and 3, the substrate loading apparatus 30 according to some embodiments of the present inventive concepts may include a housing 31, a substrate support 32, a transfer module 33 (e.g., a transfer track), and a particle removal device 35. The substrate loading apparatus 30 may be connected to a gas supply apparatus 37 and a gas removal apparatus 39 that are positioned outside the substrate loading apparatus 30. According to an embodiment of the present inventive concepts, the gas supply apparatus 37 may provide the substrate loading apparatus 30 with an inert gas (e.g., nitrogen and/or argon). Thus, the substrate loading apparatus 30 may have an increased internal pressure. The gas removal apparatus 39 may remove gas such as air in the substrate loading apparatus 30. Thus, the substrate loading apparatus 30 may have a reduced internal pressure. For example, the gas removal apparatus 39 may include a pump. The transfer module 33, the particle removal device 35, the gas supply apparatus 37, and the gas removal apparatus 39 may be controlled, for example, by a controller.

Although not illustrated, the controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the processing controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the processing controller, and a bus that allows communication among the various disclosed components of the processing controller.

The housing 31 may provide a space in which the substrate WF may be disposed. The housing 31 may be sealed. For example, a space in which the substrate WF is disposed may be a space isolated from the outside. The substrate WF may be disposed flat in the housing 31. For example, the substrate WF may be disposed to allow its surface to be parallel to a first direction D1 and a second direction D2. The first direction D1 and the second direction D2 may intersect each other. A third direction D3 may intersect the first direction D1 and the second direction D2. For example, each of the first direction D1 and the second direction D2 may correspond to a horizontal direction, and the third direction D3 may correspond to a vertical direction.

The housing 31 may have a first slit 31a and a second slit 31b that penetrate in the second direction D2 through the housing 31. The first slit 31a may penetrate one lateral surface of the housing 31. The second slit 31b may penetrate another lateral surface that is opposite to the one lateral surface of the housing 31 that the first slit 31a penetrates. The first slit 31a and the second slit 31b may be spaced apart from each other in the second direction D2. The first slit 31a and the second slit 31b may each be sized to allow the substrate WF to pass therethrough. The substrate WF may enter or exit the housing 31 through the first slit 31a and the second slit 31b. For example, the substrate WF may move through the first slit 31a to the housing 31 in the interface module 20 of FIG. 1, and the substrate WF in the housing 31 may move through the second slit 31b to the substrate transfer apparatus 40 of FIG. 1.

According to an embodiment of the present inventive concepts, the housing 31 may have an exhaust hole 31h on a bottom surface thereof (see, e.g., FIG. 3). A gas in the housing 31 may be outwardly discharged through the exhaust hole 31h. Thus, the housing 31 may have a reduced internal pressure, and the substrate loading apparatus 30 may adopt a low vacuum state and a high vacuum state. For example, the exhaust hole 31h may be connected to the gas removal apparatus 39, but the present inventive concepts are not limited thereto. For example, the exhaust hole 31h may be connected to a pump different from a pump included in the gas removal apparatus 39.

The substrate support 32 may be positioned on a lower side in the housing 31. The substrate support 32 may be connected and fixed to the housing 31. For example, the substrate support 32 may be fixed and immovable on a certain position. The substrate WF may be disposed on the substrate support 32. The substrate support 32 may contact opposite side portions of the substrate WF to support the substrate WF. Thus, the substrate WF may be spaced apart from the housing 31. For example, the substrate support 32 may be a component for supporting the substrate WF such that the substrate WF may be positioned on a certain location in the housing 31.

The transfer module 33 may be positioned in the housing 31 on an upper side of the housing 31. The transfer module 33 may be positioned on (e.g., above) the substrate WF. The transfer module 33 may include a first rail 33a (e.g., a first track or first transfer track) and a second rail 33b (e.g., a second track or second transfer track) on the first rail 33a. For example, the first rail 33a may be combined with (e.g., coupled with or attached to) the housing 31, and the second rail 33b may be coupled to the first rail 33a. The first rail 33a may have a shape that extends along the second direction D2, and the second rail 33b may have a shape that extends along the first direction D1. Thus, the second rail 33b may move in the second direction D2 along the first rail 33a. Each of the first rail 33a and the second rail 33b may include a driving mechanism (e.g., a motor, an actuator, and so forth).

The particle removal device 35 may be positioned in the housing 31 on an upper side of the housing 31. The particle removal device 35 may be positioned on (e.g., above) and spaced apart in the third direction D3 from the substrate WF. The particle removal device 35 may be connected to the transfer module 33. For example, the particle removal device 35 may be combined with the second rail 33b of the transfer module 33 and movable in the first direction DI along the second rail 33b. The first rail 33a may allow the second rail 33b to move in the second direction D2, and the second rail 33b may allow the particle removal device 35 to move in the first direction D1. As a result, the first rail 33a and the second rail 33b of the transfer module 33 may allow the particle removal device 35 to move in any horizontal direction (e.g., in any combination of the first direction D1 and the second direction D2).

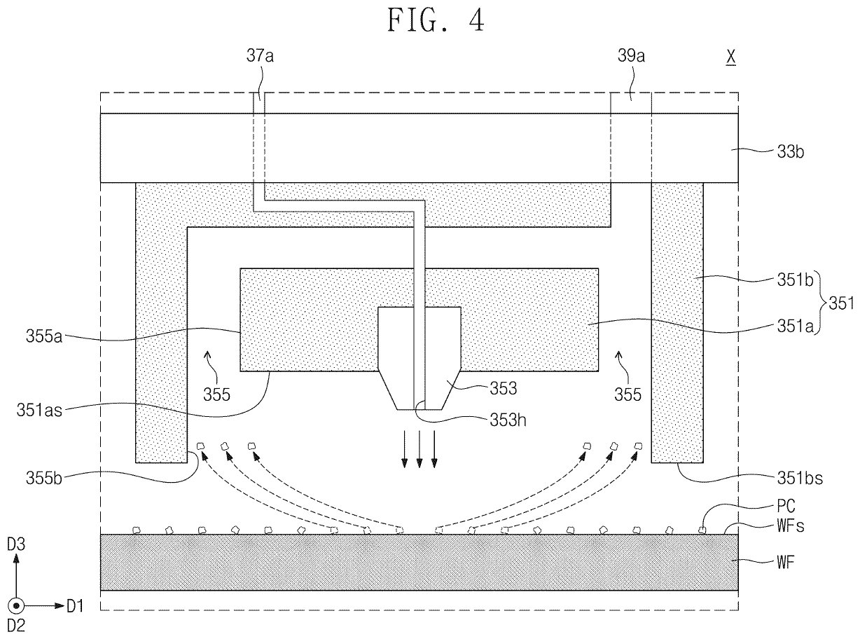

The particle removal device 35 may include a module housing 351, a nozzle 353, and an intake hole 355. In addition, the particle removal device 35 may be connected through a first pipe 37a to the gas supply apparatus 37 and through a second pipe 39a to the gas removal apparatus 39. For example, the first pipe 37a and the second pipe 39a may include an air tube and/or a flexible tube. The particle removal device 35 will be further discussed in detail with reference to FIGS. 4 to 6.

According to an embodiment of the present inventive concepts, a vertical driving mechanism (e.g., a motor, an actuator, and so forth) may be further provided between the particle removal device 35 and the second rail 33b. The vertical driving mechanism may drive the particle removal device 35 to move in the third direction D3. Therefore, the particle removal device 35 may move toward or away from the substrate WF.

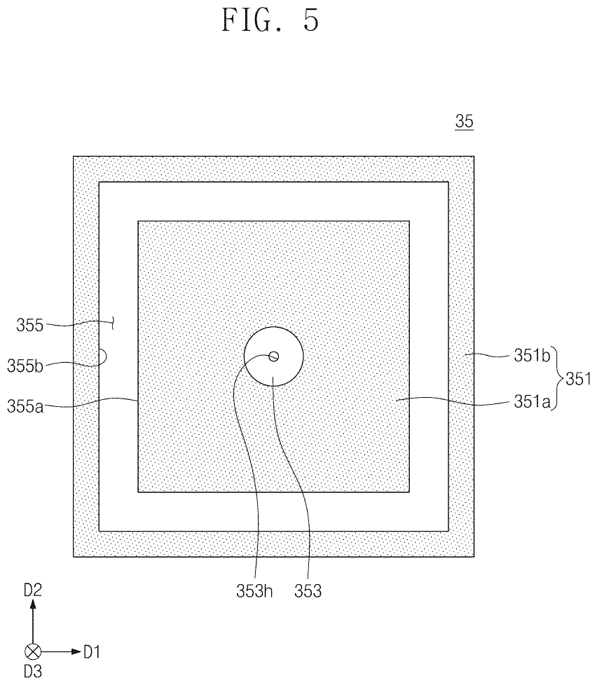

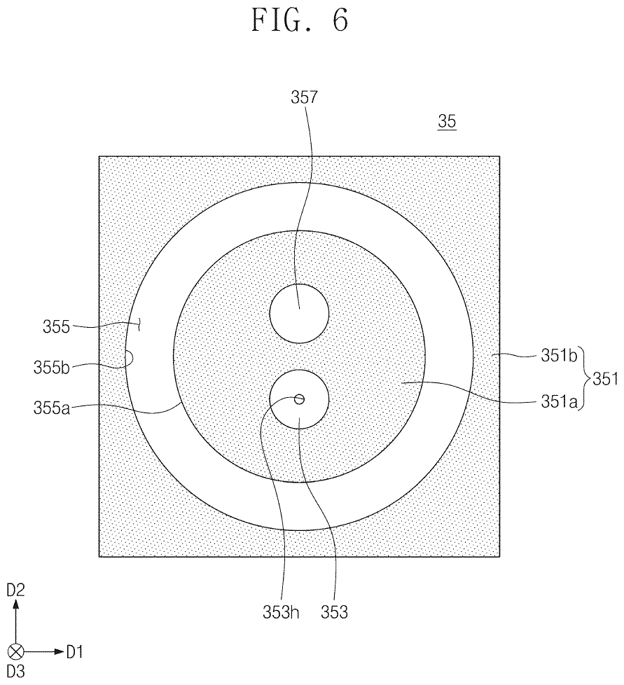

FIG. 4 illustrates an enlarged view of section X depicted in FIG. 3, showing a particle removal device 35 according to some embodiments of the present inventive concepts. FIGS. 5 and 6 illustrate bottom views showing a particle removal device according to some embodiments of the present inventive concepts.

Referring to FIGS. 4 and 5, the module housing 351 of the particle removal device 35 may include a first part 351a and a second part 351b. The first part 351a may correspond to a central region (e.g., an inner region or a first region) of the module housing 351, and the second part 351b may correspond to an edge region (e.g., an outer region or a second region) of the module housing 351. When viewed in plan, the second part 351b may surround the first part 351a. When viewed in plan, the first part 351a and the second part 351b may be spaced apart from each other across the intake hole 355 which will be discussed below.

Each of the first part 351a and the second part 351b may have a bottom surface (e.g., a bottommost surface that is the closest surface to the substrate WF and/or to the substrate support 32). A bottom surface 351as of the first part 351a may be located at a level higher than that of a bottom surface 351bs of the second part 351b. In this description, the term “level” may refer to a height in the third direction D3 from a surface WFs of the substrate WF. For example, the bottom surface 351bs of the second part 351b may be closer than the bottom surface 351as of the first part 351a to the surface WFs of the substrate WF. In this configuration, the edge region of the module housing 351 may be closer than the central region of the module housing 351 to the substrate WF.

The nozzle 353 (e.g., a blower) of the particle removal device 35 may be connected to the module housing 351 of the particle removal device 35. For example, the nozzle 353 may be combined with (e.g., coupled to or attached to) the first part 351a of the module housing 351. The nozzle 353 may be positioned on the central region of the module housing 351. The nozzle 353 may have an injection hole 353h therein. The injection hole 353h may be connected through the first pipe 37a to the gas supply apparatus 37 of FIG. 3. The injection hole 353h may be supplied with a gas from the gas supply apparatus 37 of FIG. 3 to inject the gas toward the surface WFs of the substrate WF. Therefore, contaminant particles PC present on the surface WFs of the substrate WF may be detached from the substrate WF.

The intake hole 355 (e.g., a vacuum) of the particle removal device 35 may be positioned in the module housing 351. For example, the module housing 351 may have the intake hole 355 formed therein. When viewed in plan, the intake hole 355 may be positioned between the first part 351a and the second part 351b of the module housing 351. When viewed in plan, the intake hole 355 may surround the nozzle 353 and may surround the first part 351a of the module housing 351. For example, the outer edge of the intake hole 355, when viewed in plan, may have a tetragonal planar shape. For example, the inner edge of the intake hole 355, when viewed in plan, may have a tetragonal planar shape. However, the inventive concept is not limited thereto and the outer and inner edges of the intake hole 355, when viewed in plan, may have other shapes and may be different from each other. The intake hole 355 may be connected through the second pipe 39a to the gas removal apparatus 39 of FIG. 3. The contaminant particles PC detached from the substrate WF may be removed with air through the intake hole 355 by the gas removal apparatus 39 of FIG. 3.

The intake hole 355 may have an inner surface 355a and an outer surface 355b that faces the inner surface 355a. The inner surface 355a of the intake hole 355 may be closer than the outer surface 355b of the intake hole 355 to the nozzle 353. For example, the inner surface 355a of the intake hole 355 may be an outer surface of the first part 351a of the module housing 351. The outer surface 355b of the intake hole 355 may be an inner surface of the second part 351b of the module housing 351. Thus, the outer surface 355b of the intake hole 355 may have a shape that extends further than the inner surface 355a of the intake hole 355 toward the substrate WF and/or to the substrate support 32. As a result, the outer surface 355b of the intake hole 355 may be closer than the inner surface 355a of the intake hole 355 to the substrate WF and/or the substrate support 32.

Referring to FIGS. 4 and 6, the particle removal device 35 may further include a measurement apparatus 357 on a bottom surface thereof. The measurement apparatus 357 may be positioned on a bottom surface 351as of the first part 351a of the module housing 351, while being adjacent to the nozzle 353. For example, the measurement apparatus 357 may be positioned on the central region of the module housing 351, but the present inventive concepts are not limited thereto. The measurement apparatus 357 may determine positions of the contaminant particles PC present on the surface WFs of the substrate WF. For example, the measurement apparatus 357 may include an automated optic inspection (AOI) apparatus that may include, for example, a camera.

When viewed in plan, the intake hole 355 of the particle removal device 35 may have a circular shape (e.g., a ring shape). The present inventive concepts, however, are not limited thereto. When viewed in plan, the intake hole 355 may be provided in the form of an oval shape, a triangular shape, a polygonal shape, or any other suitable shape that surrounds the nozzle 353. When viewed in plan, the inner edge of the intake hole 355 of the particle removal device 35 may be surrounded by or encompassed by the outer edge thereof.

Referring back to FIGS. 4 and 6, the particle removal device 35 according to some embodiments of the present inventive concepts may include a nozzle 353 that injects a gas and an intake hole 355 that is adjacent to and surrounds the nozzle 353 when viewed in plan. A gas injected through the nozzle 353 may detach, from the substrate WF, the contaminant particles PC present on the surface WFs of the substrate WF. The contaminant particles PC detached from the substrate WF may be removed through the intake hole 355. Therefore, it may be possible to remove the contaminant particles PC present on the surface WFs of the substrate WF. Accordingly, defects of semiconductor devices may be prevented to increase productivity and yield of semiconductor devices. In addition, the second part 351b of the module housing 351 may be closer than the first part 351a of the module housing 351 to the substrate WF. When viewed in vertical cross-section, the module housing 351 may have a shape in which the edge region encloses the central region. Thus, the contaminant particles PC detached from the substrate WF may be prevented from being scattered outside the particle removal device 35. Hence, the contaminant particles PC may be effectively eliminated.

The particle removal device 35 according to some embodiments of the present inventive concepts may further include a measurement apparatus 357. As the measurement apparatus 357 determines positions of the contaminant particles PC, the particle removal device 35 may operate only on a location where the contaminant particles PC are present. Hence, the contaminant particles PC may be effectively removed.

FIGS. 7 to 9 illustrate diagrams showing a substrate processing apparatus according to some embodiments of the present inventive concepts.

Referring to FIG. 7, the substrate processing apparatus 50 according to an embodiment of the present inventive concepts may be a semiconductor facility configured to perform a physical vapor deposition (PVD) process. For example, the substrate processing apparatus 50 may include a deposition chamber 511, a heater chuck 512, a plasma electrode 513, a source target 515, and a heat shield 516.

The deposition chamber 511 may provide a deposition space 511h. The deposition space 511h may be a space where a semiconductor process is performed. The heater chuck 512 may be positioned in the deposition space 511h. The substrate WF may be positioned on the heater chuck 512. The heater chuck 512 may include a heater therein and heat the substrate WF.

The plasma electrode 513 may be disposed in the deposition space 511h and positioned on the heater chuck 512. The plasma electrode 513 may be connected to a power supply 514. The power supply 514 may supply the plasma electrode 513 with a radio-frequency power to form a plasma in the deposition space 511h.

The source target 515 may be rigidly held on a bottom surface of the plasma electrode 513. The source target 515 may include a source of a thin layer deposition on the substrate WF. For example, the plasma formed in the deposition space 511h may from source particles from the source target 515, and the source particles may be deposited on the substrate WF to form a thin layer.

The heat shield 516 may be positioned between the deposition chamber 511 and the heater chuck 512 and between the deposition chamber 511 and the plasma electrode 513. The heat shield 516 may surround lateral surfaces of the heater chuck 512 and the plasma electrode 513. The heat shield 516 may include a heater therein and control a temperature of the deposition space 511h.

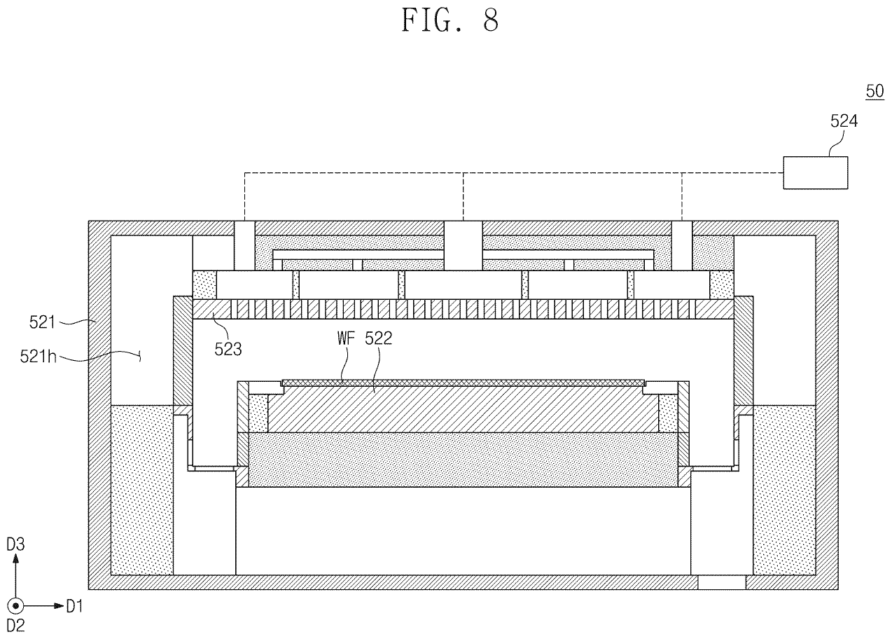

Referring to FIG. 8, the substrate processing apparatus 50 according to an embodiment of the present inventive concepts may be a semiconductor facility configured to use a plasma to perform an etching process. For example, the substrate processing apparatus 50 may include an etching chamber 521, an electrostatic chuck 522, a shower head 523, and a gas supply 524.

The etching chamber 521 may provide an etching space 521h. The etching space 521h may be a space where a semiconductor process is performed. The electrostatic chuck 522 may be positioned in the etching space 521h. The substrate WF may be disposed on the electrostatic chuck 522, and the electrostatic chuck 522 may rigidly hold the substrate WF.

The gas supply 524 may supply a process gas. The process gas supplied from the gas supply 524 may move through the shower head 523 to the etching space 521h. The shower head 523 may have a plurality of holes. The holes of the shower head 523 may uniformly provide (e.g., disperse) the process gas in the etching space 521h.

In the etching space 521h, a plasma may be formed on the substrate WF. The plasma may decompose the process gas. The decomposed process gas may move on the substrate WF to etch a portion of the substrate WF.

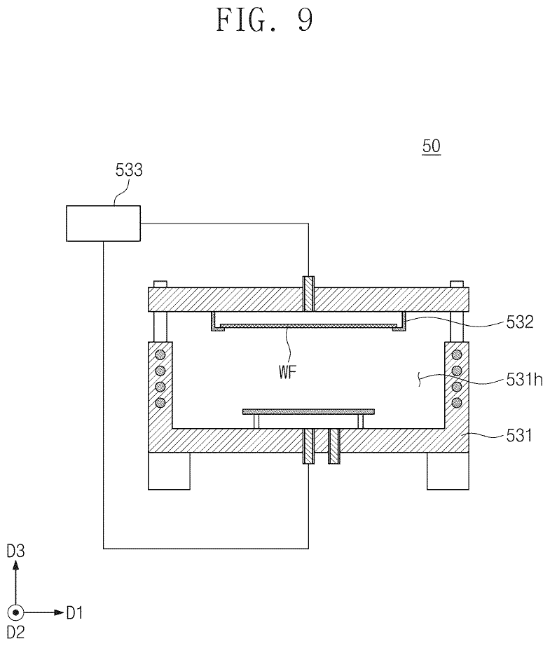

Referring to FIG. 9, the substrate processing apparatus 50 according to an embodiment of the present inventive concepts may be a semiconductor facility configured to use a fluid to perform a cleaning process. For example, the substrate processing apparatus 50 may include a cleaning chamber 531, a cleaning stage 532, and a fluid supply 533.

The cleaning chamber 531 may provide a cleaning space 531h. The cleaning space 531h may be a space where a semiconductor process is performed. The cleaning chamber 531 may include a heater therein and control a temperature of the cleaning space 531h. The cleaning stage 532 may be positioned in the cleaning space 531h. The substrate WF may be disposed on the cleaning stage 532.

The fluid supply 533 may supply a fluid. The fluid supply 533 may be connected to upper and/or lower portions of the cleaning chamber 531. The fluid supplied from the fluid supply 533 may move to the substrate WF on the cleaning stage 532. The fluid may be, for example, a supercritical fluid (SCF) of carbon dioxide (CO₂). The fluid may remove unnecessary materials present on the substrate WF.

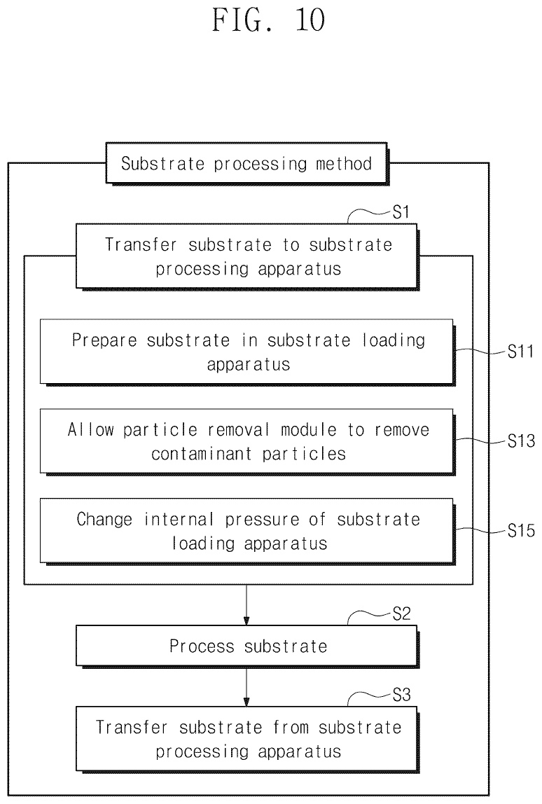

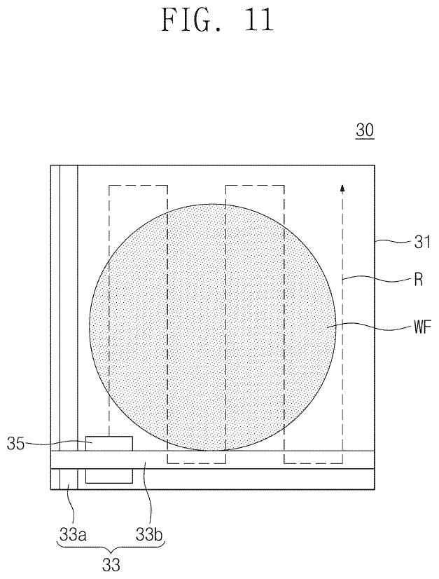

FIG. 10 illustrates a flow chart showing a substrate processing method according to some embodiments of the present inventive concepts. FIG. 11 illustrates a diagram showing a method of removing contaminant particles according to some embodiments of the present inventive concepts.

Referring to FIG. 10, a substrate processing method may be provided. The substrate processing method according to some embodiments of the present inventive concepts may be a way of processing a substrate by using the substrate processing system 1 discussed with reference to FIGS. 1 to 9. The substrate processing method may include transferring a substrate to a substrate processing apparatus (S1), processing the substrate (S2), and transferring the substrate from the substrate processing apparatus (S3).

The transferring of the substrate to the substrate processing apparatus (S1) may include preparing the substrate in a substrate loading apparatus (S11), allowing a particle removal device to remove contaminant particles (S13), and changing an internal pressure of the substrate loading apparatus (S15).

Referring to FIGS. 1 to 3, the FOUP 11 may be disposed on the load port 10 of the substrate processing system 1. The first robot arm 21 of the interface module 20 may transfer the substrate WF stored in the FOUP 11 to the substrate loading apparatus 30. For example, the substrate WF may move to the substrate loading apparatus 30 through the first slit 31a of the substrate loading apparatus 30. The substrate WF may be positioned on the substrate support 32 in the substrate loading apparatus 30. The preparing of the substrate in the substrate loading apparatus (S11) may include placing the substrate WF on the substrate support 32 of the substrate loading apparatus 30.

Referring to FIGS. 4 and 11, the allowing of the particle removal device 35 to remove the contaminant particles (S13) may include allowing the particle removal device 35 to inject a gas onto the surface WFs of the substrate WF, allowing the particle removal device 35 to remove the contaminant particles PC through the intake hole 355, and allowing the particle removal device 35 to move on the substrate WF. For example, the particle removal device 35 may remove the contaminant particles PC by injecting a gas onto the surface WFs of the substrate WF, remove the contaminant particles PC through the intake hole 355, and then may move with respect to the substrate WF to perform the particle removal process on a different portion of the substrate WF.

The nozzle 353 of the particle removal device 35 may inject a gas onto the surface WFs of the substrate WF. A gas pressure may cause the contaminant particles PC present on the surface WFs of the substrate WF to be detached from the surface WF. The gas removal apparatus 39 of FIG. 3 may force the intake hole 355 of the particle removal device 35 to have a lower pressure than that of the surrounding environment. Therefore, the intake hole 355 may receive the contaminant particles PC detached from the substrate WF to remove the contaminant particles PC from the substrate WF.

The particle removal device 35 may move along a traveling path R on the substrate WF. The traveling of the particle removal device 35 may be performed using the transfer module 33. The particle removal device 35 may move along the second direction D2 on the first rail 33a of the transfer module 33. The particle removal device 35 may move along the first direction DI on the second rail 33b of the transfer module 33. For example, the particle removal device 35 may move along the first direction D1 and the second direction D2 parallel to the surface WFs of the substrate WF. As a result, the particle removal device 35 may move while scanning the surface WFs of the substrate WF.

According to an embodiment of the present inventive concepts, the allowing of the particle removal device 35 to inject the gas onto the surface WFs of the substrate WF, the allowing of the particle removal device 35 to remove the contaminant particles PC through the intake hole 355, and the allowing of the particle removal device 35 to move on the substrate WF may be performed simultaneously. Therefore, the particle removal device 35 may move while removing the contaminant particles PC present on the surface WFs of the substrate WF. Accordingly, it may be possible to remove the contaminant particles PC present on the surface WFs of the substrate WF.

Referring to FIGS. 1 to 3, the interface module 20 may maintain its atmospheric pressure state, and the substrate transfer apparatus 40 may maintain its high vacuum state. When the substrate loading apparatus 30 is in the atmospheric pressure state, the substrate WF may be transferred between the interface module 20 and the substrate loading apparatus 30. When the substrate loading apparatus 30 is in the high vacuum state, the substrate WF may be transferred between the substrate loading apparatus 30 and the substrate transfer apparatus 40. For example, when the substrate WF is transferred from the FOUP 11 to the substrate processing apparatus 50, the substrate loading apparatus 30 may be changed from the atmospheric pressure state into the high vacuum state. In this sense, the changing of the internal pressure in the substrate loading apparatus (S15) may include lowering an internal pressure of the substrate loading apparatus 30.

The changing of the internal pressure in the substrate loading apparatus (S15) may include changing the internal pressure of the substrate loading apparatus 30 from atmospheric pressure to low vacuum (e.g., a first pressure lower than the atmospheric pressure), and changing the internal pressure of the substrate loading apparatus 30 from low vacuum to high vacuum (e.g., a second pressure lower than the first pressure). The particle removal device 35 connected to the gas removal apparatus 39 may remove air in the substrate loading apparatus 30, while removing the contaminant particles PC present on the surface WFs of the substrate WF. Thus, the substrate loading apparatus 30 may have a reduced internal pressure. During the operation of the particle removal device 35, the internal pressure of the substrate loading apparatus 30 may continuously decrease. Therefore, the internal pressure of the substrate loading apparatus 30 may be changed from atmospheric pressure to low vacuum. The changing of the internal pressure in the substrate loading apparatus 30 from atmospheric pressure to low vacuum may be performed simultaneously with the allowing of the particle removal device to remove the contaminant particles (S13).

After the removal of the contaminant particles PC by the particle removal device 35, the exhaust hole 31h of the substrate loading apparatus 30 may be opened (e.g., by a controller). Air in the substrate loading apparatus 30 may be discharged through the exhaust hole 31h. Therefore, the internal pressure of the substrate loading apparatus 30 may be changed from low vacuum to high vacuum. In this description, the low vacuum may refer to a pressure from the atmospheric pressure to about 1 Torr, and the high vacuum may refer to a pressure of about 0.01 mTorr or less.

According to an embodiment of the present inventive concepts, the transferring the substrate from the substrate processing apparatus (S1) may further include measuring the surface WFs of the substrate WF. In this case, the particle removal device 35 may further include the measurement apparatus 357 as discussed with reference to FIG. 6. The measuring the surface WFs of the substrate W may be performed before the allowing of the particle removal device to remove the contaminant particles (S13). For example, the particle removal device 35 may move along the traveling path R of FIG. 11, and the measurement apparatus 357 may measure the surface WFs of the substrate WF to determine positions of the contaminant particles PC. Afterwards, the particle removal device 35 may selectively move to a location where the contaminant particles PC are positioned, thereby removing the contaminant particles PC. Accordingly, the contaminant particles PC may be effectively eliminated.

Referring to FIGS. 7 to 9, the processing of the substrate (S2) may include one of using a physical vapor deposition process to deposit a thin layer on one surface of the substrate WF, using a plasma etching process to etch the one surface of the substrate WF, and using a cleaning process to clean the one surface of the substrate WF. The present inventive concepts, however, are not limited thereto.

Referring back to FIGS. 1 to 4, the substrate WF processed by the substrate processing apparatus 50 may move back to the FOUP 11. For example, the second robot arm 41 of the substrate transfer apparatus 40 may transfer the processed substrate WF to the substrate loading apparatus 30. In the substrate loading apparatus 30, the particle removal device 35 may remove the contaminant particles PC present on the surface WFs of the processed substrate WF, and this step may be substantially the same as the allowing of the particle removal device to remove the contaminant particles (S13) discussed above. As the substrate transfer apparatus 40 is in the high vacuum state, and as the interface module 20 is in the atmospheric state, the substrate loading apparatus 30 may have an increased internal pressure. For example, the transferring the substrate from the substrate processing apparatus (S3) may include preparing the processed substrate WF in the substrate loading apparatus 30, allowing the particle removal device 35 to remove the contaminant particles PC present on the surface WFs of the processed substrate WF, and changing the internal pressure of the substrate loading apparatus. As a result, the transferring the substrate from the substrate processing apparatus (S3) may be substantially the same as the transferring the substrate to the substrate processing apparatus (S1).

In a substrate processing method according to some embodiments of the present inventive concepts, before and after the substrate WF is processed, the contaminant particles PC present on the surface WFs of the substrate WF may be removed in the substrate loading apparatus 30 of the substrate processing system 1. In addition, as the contaminant particles PC are removed in the substrate processing system 1, it may be possible to reduce a time required for removing the contaminant particles PC. Therefore, failure of semiconductor devices may be prevented, and productivity of semiconductor devices may be increased.

A substrate loading apparatus according to some embodiments of the present inventive concepts may include a particle removal device, and the particle removal device may include a nozzle and an intake hole that surrounds the nozzle when viewed in plan. A gas injected through the nozzle may detach contaminant particles present on a surface of a substrate, and the contaminant particles may be removed through the intake hole from the substrate. In addition, when viewed in vertical section, a module housing may have a shape in which an edge region encloses a central region. Thus, the contaminant particles detached from the substrate may be prevented from being scattered outside the particle removal device. Accordingly, it may be possible to avoid failure and/or defects of semiconductor devices.

In a substrate processing method according to some embodiments of the present inventive concepts, before and after a substrate is processed, contaminant particles present on a surface of a substrate may be removed in a substrate loading apparatus of a substrate processing system. As the contaminant particles are effectively removed, productivity of semiconductor devices may be increased.

Although the present invention has been described in connection with the embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A substrate loading apparatus, comprising:
a housing that provides a space where a substrate is configured to be disposed;
a transfer track in the housing on an upper side of the housing; and
a particle removal device connected to the transfer track,
wherein the particle removal device includes:
a nozzle configured to inject a gas; and
a module housing that has an intake hole, and
wherein, when viewed in plan, the intake hole surrounds the nozzle.

2. The substrate loading apparatus of claim 1, wherein the transfer track is configured to horizontally move the particle removal device.

3. The substrate loading apparatus of claim 2, wherein the transfer track is further configured to vertically move the particle removal device.

4. The substrate loading apparatus of claim 1, wherein the module housing includes:
a first part; and
a second part that surrounds the first part, when viewed in plan,
wherein a bottom surface of the second part is closer than a bottom surface of the first part to a lower side of the housing.

5. The substrate loading apparatus of claim 1, wherein
the nozzle of the particle removal device is connected to a gas supply apparatus, and
the intake hole of the particle removal device is connected to a pump.

6. The substrate loading apparatus of claim 1, further comprising an automated optic inspection apparatus on a bottom surface of the particle removal device.

7. A substrate processing system, comprising:
a substrate loading apparatus that includes a transfer track and a particle removal device that are connected to each other; and
a substrate processing apparatus connected to the substrate loading apparatus,
wherein the particle removal device includes a nozzle and an intake hole adjacent to the nozzle, and
wherein the transfer track is configured to move the particle removal device.

8. The substrate processing system of claim 7, wherein the transfer track is configured to drive the particle removal device to move in a first direction and a second direction different from the first direction.

9. The substrate processing system of claim 7, wherein, when viewed in plan, the intake hole surrounds the nozzle.

10. The substrate processing system of claim 7, wherein
a substrate is configured to be disposed in the substrate loading apparatus, and
the nozzle is configured to inject a gas onto a surface of the substrate.

11. The substrate processing system of claim 10, wherein the intake hole has:
an inner surface adjacent to the nozzle; and
an outer surface that faces the inner surface,
wherein the outer surface extends further than the inner surface toward a lower side of the substrate loading apparatus.

12. The substrate processing system of claim 7, wherein the substrate processing apparatus includes a physical vapor deposition process facility.

13. A substrate processing method, comprising:
transferring a substrate to a substrate processing apparatus; and
processing the substrate,
wherein the transferring of the substrate includes:
preparing the substrate in a substrate loading apparatus that includes a particle removal device;
removing contaminant particles on the substrate using the particle removal device; and
changing an internal pressure of the substrate loading apparatus,
wherein the removing of the contaminant particles includes moving the particle removal device on the substrate.

14. The substrate processing method of claim 13, wherein the particle removal device includes a nozzle and an intake hole, and
wherein the removing of the contaminant particles includes:
injecting a gas through the nozzle to detach the contaminant particles from the substrate; and
removing the contaminant particles through the intake hole.

15. The substrate processing method of claim 13, wherein the removing of the contaminant particles and the changing of the internal pressure of the substrate loading apparatus are performed simultaneously.

16. The substrate processing method of claim 13, wherein the transferring of the substrate to the substrate processing apparatus further includes measuring a surface of the substrate before the removing of the contaminant particles.

17. The substrate processing method of claim 13, wherein the changing the internal pressure of the substrate loading apparatus includes:
changing the internal pressure from atmospheric pressure to a first pressure lower than the atmospheric pressure; and
changing the internal pressure from the first pressure to a second pressure lower than the first pressure.

18. The substrate processing method of claim 13, wherein the moving of the particle removal device on the substrate includes moving the particle removal device in a first direction and a second direction that are parallel to a surface of the substrate.

19. The substrate processing method of claim 13, wherein the processing of the substrate includes performing a physical vapor deposition process.

20. The substrate processing method of claim 13,
further comprising transferring the processed substrate from the substrate processing apparatus after the processing of the substrate,
wherein the transferring of the processed substrate from the substrate processing apparatus includes:
preparing the processed substrate in the substrate loading apparatus;
removing contaminant particles on the processed substrate using the particle removal device; and
increasing an internal pressure of the substrate loading apparatus.
